(19) United States
(12) Patent Application Publication
(10) Pub. No.: US 2014/0211412 A1
(43) Pub. Date: Jul. 31, 2014

(54) HARD DRIVE COOLING FOR FLUID SUBMERSION COOLING SYSTEMS

(71) Applicant: Christiaan Scott Best, Austin, TX (US)

(72) Inventor: Christiaan Scott Best, Austin, TX (US)

(73) Assignee: Green Revolution Cooling, Inc., Austin, TX (US)

(21) Appl. No.: 14/237,100

(22) PCT Filed: Aug. 4, 2012
(86) PCT No.: PCT/US12/49668

§ 371 Date: Feb. 4, 2014

Related U.S. Application Data
(60) Provisional application No. 61/574,601, filed on Aug. 5, 2011.

(51) Int. Cl. H05K 7/20

(52) U.S. Cl. CPC H05K 7/20236
USPC 361/679.47

(57) ABSTRACT

Hard disk drives and computing systems to which they are connected are cooled by submerging the computing systems into a dielectric liquid coolant in a tank and by thermally coupling the hard disk drives to a heat conductive extension that is partly submerged into the coolant and partly out of the coolant. To keep the hard disks drives out of the coolant, they are mounted to the part of the heat conductive extension that is out of the coolant. In such a configuration, the hard disk drives are cooled through conduction of the heat from the hard disk drive to the coolant via the heat conductive extension. A pump may be used to move warmer coolant from the tank into a heat exchanger where the coolant is cooled and to move the cooled coolant back into the tank.

### CROSS-REFERENCES TO RELATED APPLICATIONS

This application claims priority pursuant to 35 U.S.C. 119 to U.S. provisional application Ser. No. 61/574,601 entitled HARD DRIVE ENCASEMENT AND HEAT TRANSFER FOR FLUID SUBMERSION SYSTEMS filed on Aug. 5, 2011.

### BACKGROUND OF THE INVENTION

1. Technical Field

The present invention is directed generally to hard disk drives of computing systems. More specifically, the present invention is directed to an apparatus, system and method of cooling hard disk drives of computing systems.

2. Description of Related Art

Nearly every computing system in use today makes use of one or more hard disk drives (“HDDs”). A computing system is a device that uses a processor to process data. An HDD is a device that is used for storing and retrieving digital information such as data. The HDD consists of one or more rigid or hard disks or platters that are rapidly rotating and which are coated with a magnetic material. The HDD also has magnetic heads arranged to write data to and read data from the magnetized platters.

Referring to the figures, which use like reference numbers to denote like parts, FIG. 1a depicts an exemplary HDD 100. The HDD 100 has a top cover removed to expose some of its internal components. The exposed internal components include a plurality of platters 110, a plurality of read and write heads 130 each being associated with a corresponding platter and connected to a head arm 120 for reading data from and writing data to the HDD 100. The exemplary HDD 100 also includes an electric motor (not shown) for rotating the platters 110 and another electric motor (again not shown) for moving the head arm 120.

FIG. 1b shows a cross-sectional view of the exemplary HDD 100. In this view, the plurality of platters 110 is clearly visible. Also in this view is shown a printed circuit board (PCS) 140 for associated electronics to control the head arm 120, rotation of the platters 110, and to perform readings and writings of data on the HDD 100 as directed by a disk controller (not shown). The HDD 100 may also include firmware that minimizes access time to data and thus maximizing drive performance.

As is shown in FIG. 1b, the platters 110 are located into an enclosure 150. Ambient air within the enclosure 150 is fluidly connected to external ambient air through a small breather hole under air filter 140 (see FIG. 1a). The air filter 140 is used to remove leftover contaminants from manufacture, any particles or chemicals that may have somehow entered the enclosure, and any particles or gas generated internally in normal operation.

In addition to keeping the enclosed ambient air connected to the external ambient air, the small hole under the air filter 140 is used to maintain a particular pressure within the enclosure 150. For example in operation, the platters 110 rotate around a central axis or spindle 160 at a constant speed. The head arm 120 moves the read and write heads 130 radially as the platters 110 rotate, allowing access to the entire platters' surface. The read and write heads 130 store data as tiny magnetized regions, called bits, on a disk (or platter). A magnetic orientation in one direction on the disk 110 may represent a “1”, an orientation in the opposite direction may represent a “0”.

In writing data to and reading data from the platters 110, the read and write heads 130 do not touch the surface of the platters 110. They are kept from touching the platter surface by air that is extremely close to the platters 110 and which moves at or near the platter speed. The HDD 100 relies on the air pressure maintained inside the enclosure to ensure that the read and write heads 130 are at a proper height while the platters 110 rotate. If the air pressure is too low, then the read and write heads 130 may not be lifted high enough. In such a case, the heads 130 may touch the surface of the platters 110 scraping some of the magnetic coating thereon off. At worst, this may ruin the HDD in which case all data may be lost and at best, it may result in some data loss.

In any event, the HDD 100 generates heat. For example, friction between mechanical pasts in the two electric motors generates heat. Heat is also generated by current going through the electronic components on the PCS 140. It is estimated that a modern HDD uses anywhere from two (2) to ten (10) watts of power. So, in order for an HDD to work at its optimum, it must be cooled. This is especially so in the case of computer data centers having hundreds of servers, where there may be hundreds of HDDs at one location.

Different methods have been used to cool computer systems and computer component devices, such as HDDs, that have heat-generating mechanical and electronic components embedded therein. For example, in U.S. Patent Publication No. U.S. 2011/0132579 A1 entitled LIQUID SUBMERGED, HORIZONTAL COMPUTER. SERVER RACK AND SYSTEMS AND METHODS OF COOLING SUCH A SERVER RACK, the disclosure of which is herein incorporated by reference, a fluid submersion cooling system is disclosed. In this publication, a plurality of rack-mountable computing systems is submerged in a dielectric liquid coolant for cooling the computing systems. Since one or more HDDs may be connected to a computing system, it would be desirable to use the dielectric liquid coolant used for cooling the computing systems to also cool the HDDs.

Note that dielectric liquid coolant includes without limitation vegetable oil, mineral oil (otherwise known as transformer oil), or any liquid coolant having similar features (e.g., a non-flammable, non-toxic liquid with dielectric strength better than or nearly as comparable as air).

In any case, submerging an HDD in a dielectric liquid coolant may damage or prevent the HDD from operating. As mentioned before, the ambient air within the HDD enclosure is fluidly connected to the external ambient air to maintain the pressure within the HDD enclosure. If the HDD is submerged into the dielectric liquid coolant, the air within the HDD enclosure will no longer be connected to the external ambient air without some adaptation to the drive. Hence, the pressure within the HDD enclosure may not be properly maintained. And, as mentioned above, if the pressure is not properly maintained, such as through the use of an air line between the HDD enclosure and the external ambient air, as shown in U.S. Patent Publication No. 2008/0017355, the read and write heads 130 may scrape the magnetic coating off the platters 110. Further, the dielectric liquid coolant may enter the HDD enclosure through the small breather hole under the air filter 140. Dielectric liquid coolant inside the HDD enclosure may damage or prevent the HDD from operating.

Consequently, a need exists for a cooling system that uses dielectric liquid coolant to cool rack-mountable computing systems to which one or more HDDs are electrically connected to also cool the HDDs without damaging them.

### SUMMARY OF THE INVENTION

The present invention provides an apparatus, system, and method of cooling one or more hard disk drives of one or more computing systems. The one or more hard disk drives include heat generating electronic and mechanical components that may get so hot during operation that the one or more disk drives may malfunction.

The apparatus, system, and method use a dielectric liquid coolant in a tank that has an interior volume. Further, the apparatus, system, and method use first one or more members positioned within the interior volume to mount the one or more computing systems thereon. The first one or more mounting members may be configured to allow the one or more computing systems to be at least partially submerged within the dielectric liquid coolant when the dielectric liquid coolant is in the interior volume for sufficiently cooling the one or more computing systems.

The apparatus, system, and method may further use second one or more mounting members positioned within the interior volume to mount the one or more hard disk drives thereon. The second one or more mounting members may be configured to keep the one or more hard disk drives above the dielectric liquid coolant when the dielectric liquid coolant is in the interior volume. The second one or more mounting members may have at least one heat conductive extension thermally coupled with the one or more hard disk drives at one end and immersed into the dielectric liquid coolant at another end to transfer at least a portion of the heat generated by the heat generating electronic and mechanical components of the one or more hard disk drives to the dielectric liquid coolant for absorption in order to sufficiently cool the one or more hard disk drives.

The apparatus, system, and method may further use a heat exchanger to cool the dielectric liquid coolant in the tank.

In one embodiment, the apparatus, system, and method may use a splash guard coupled to the one or more hard disk drives for protecting the one or more hard disk drives against dielectric liquid coolant splashes from circulating dielectric liquid coolant in the tank. In addition, at least one heat sink may thermally be coupled to the at least one heat conductive extension. In this case, the at least one heat sink may be immersed at one end into the dielectric liquid coolant to couple heat from the hard disk drives to the dielectric liquid coolant, thereby providing further cooling to the hard disk drive.

In another embodiment, the heat conductive extension may include an electrical connector at the end immersed in the dielectric liquid coolant, the one or more computing systems may use at least one hard disk drive slot that has a mating electrical connector therein. In such a case, the electrical connector can be connected to the one or more hard disk drives at one end and to the mating connector at another end to thereby electrically connect the one or more hard disk drives to the one or more computing systems.

In yet another embodiment, a controller may be used to maintain the dielectric liquid coolant at substantially a specific elevated temperature. The specific elevated temperature is a temperature that sufficiently cools the one or more computing systems and the one or more hard disk drives while it reduces energy consumption of the system.

In a further embodiment, a pump may be used to pump warmer dielectric liquid coolant from the interior volume and for pumping cooler dielectric liquid coolant into the interior volume. The at least one tank may include a coolant inlet and a coolant outlet, a pressure manifold on one side and a suction manifold on another side. The pressure manifold may be fluidly coupled to the coolant inlet for facilitating the flow of the cooler dielectric liquid coolant into the interior volume and the suction manifold may be fluidly coupled to the coolant outlet for facilitating the flow of the warmer dielectric liquid coolant out of the interior volume. The pressure manifold and the suction manifold may have a plurality of flow augmentation devices for enhancing and directing the flow of the dielectric liquid coolant inside the interior volume.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1a depicts an exemplary hard disk drive (HDD).

FIG. 1b shows a cross-sectional view of the exemplary HDD.

FIG. 2a depicts an exemplary system for cooling one or more servers as well as one or more HDDs simultaneously.

FIG. 2b is an alternative exemplary system to the exemplary system in FIG. 2a.

FIG. 3 depicts an exemplary mounting member or plate for mounting both servers and HDDs into a cooling tank.

FIG. 4a depicts an exemplary drive sled to which an HDD is mounted.

FIG. 4b illustrates a sled with an extension cable.

FIG. 4c depicts a server with a slot facing up.

FIG. 4d illustrates a sled having a heat sink attached on either side of it.

FIG. 5a displays two heat sinks each thermally coupled to a side of an HDD.

FIG. 5b displays a heat sink disposed over the HDD.

FIG. 6 depicts an exemplary tank with an interior volume within which servers, HDDs and dielectric liquid coolant are kept.

FIG. 7a depicts a suction manifold.

FIG. 7b shows a pressure manifold 710.

FIG. 7c is a left side view of the exemplary tank.

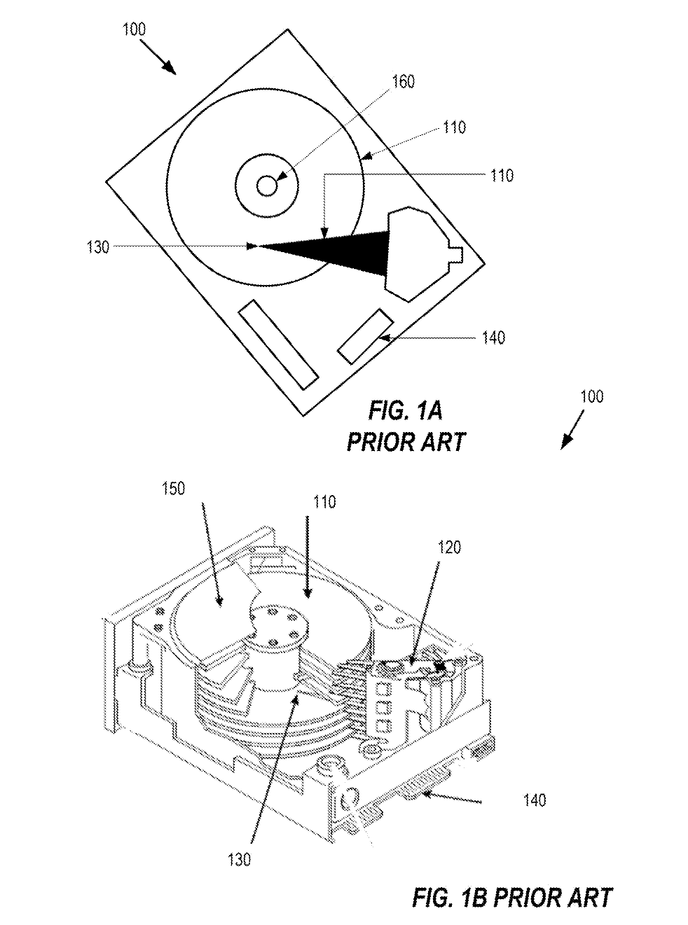

### DETAILED DESCRIPTION

In the following detailed description, reference is made to the accompanying drawings which form a part hereof, and which illustrate specific embodiments of the invention. These embodiments are described in sufficient detail to enable those of ordinary skill in the art to make and use them. It is understood that modifications may be made to the specific embodiments disclosed herein without departing from the spirit or scope of the invention.

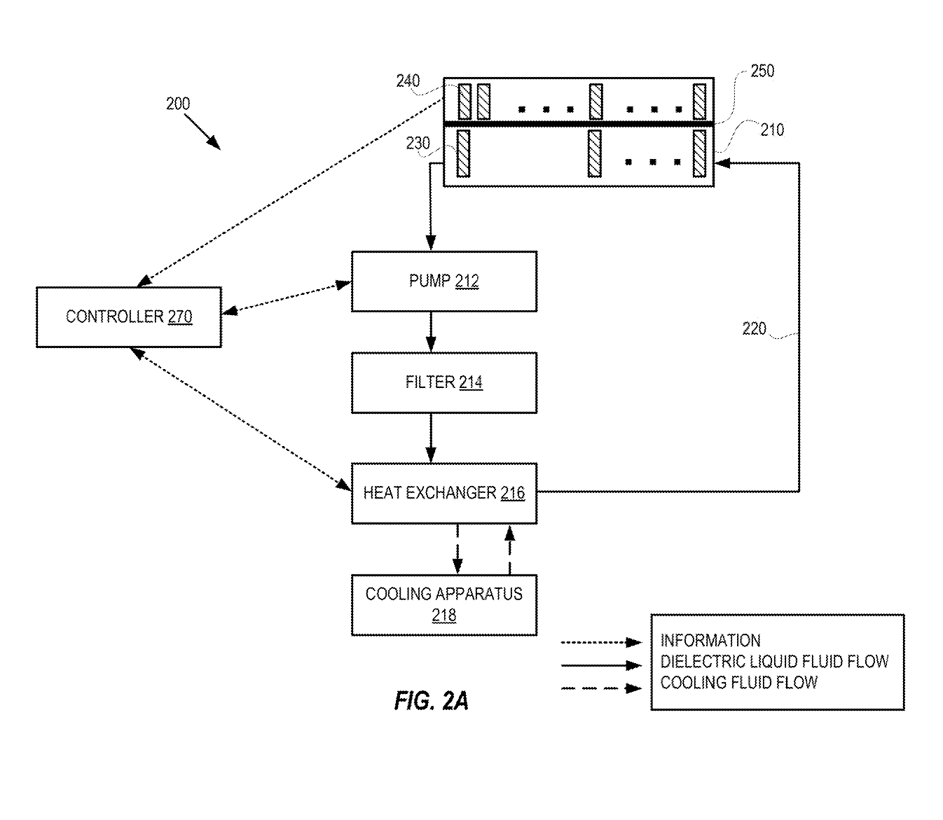

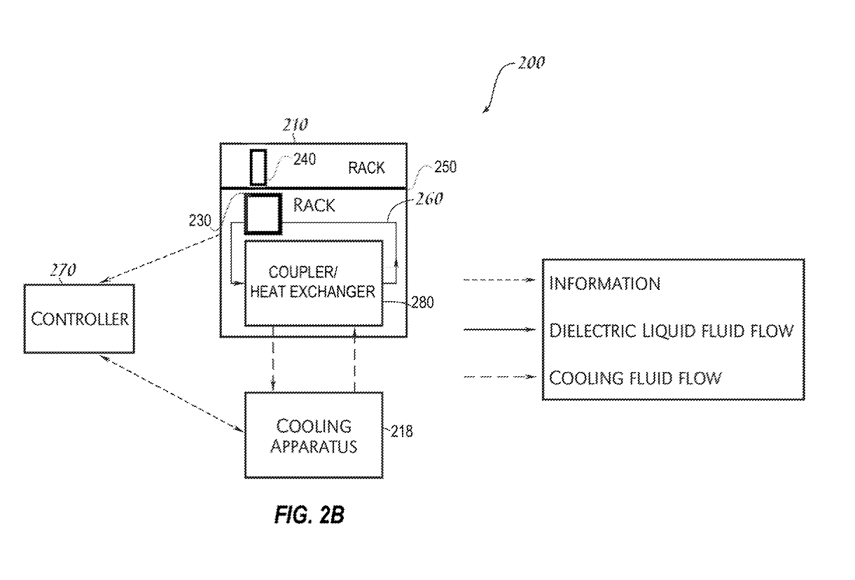

Returning to the figures, FIG. 2a depicts an exemplary system 200 for cooling one or more rack-mountable computing systems as well as one or more HDDs simultaneously. A suitable rack-mountable computing system is a conventional commercially available rack-mountable server, although other commercially available or custom rack-mountable computers may be used. Both the computing systems and HDDs may be arranged in one or more racks, for example, in a data center. A data center is a physical location housing one or more servers. A rack is a frame or enclosure that contains multiple mounting slots called bays, each designed to hold a hardware unit secured in place with fastening devices such as screws. The hardware unit may be any equipment modules. For example, the equipment modules may be computers, network routers, hard-drive arrays, data acquisition equipment, power supplies etc.

The system 200 includes a tank 210 having an interior volume containing a dielectric liquid coolant. The dielectric liquid coolant has a surface 250. Mounting members or rails to be described hereinafter are positioned within the interior volume of the tank 210 and are configured to receive and mount the plurality of computing systems 230 into the tank 210. At least a portion of each computing system 230 is submerged within the dielectric liquid coolant for sufficiently cooling each respective computing system when the tank 210 is sufficiently full of the liquid coolant. Preferably, each of the computing systems 230 during operation is below surface 250 of the dielectric liquid coolant.

As alluded to above, modern HDDs are not encased in a sealed enclosure. Consequently, submerging the HDDs 240 into the dielectric liquid coolant may ruin or damage the HDDs. Hence, the mounting members are designed such that when the HDDs are mounted thereon, the HDDs 240 remain above the surface 250 of the dielectric liquid coolant in the tank 210.

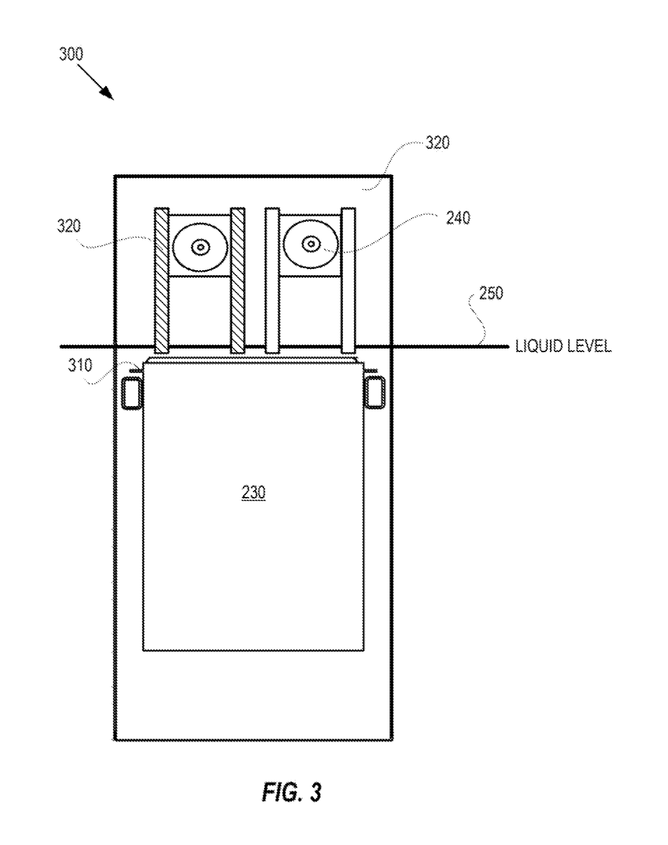

FIG. 3 depicts an exemplary mounting member or plate 300 for mounting both computing systems 230 and HDDs 240 into the tank 210 of FIG. 2a. The mounting plate 300 includes side mounted ears 310 to keep the mounting plate 300 partly within and partly out of the dielectric liquid coolant. Computing system 230 which may include motherboard, power supply and other components may be fastened to the part of the mounting plate 300 that is submerged in the dielectric liquid coolant using any of various methods (e.g., screws, slots, rails etc.). The mounting member 300 may be made of a heat conductive material 320, which may be steel, aluminum or brass. In a particular embodiment, the mounting member 300 is made of a thin sheet of aluminum.

The HDDs 240 may be electrically connected directly to a computing system for power and data transfer purposes. Then the HDDs 240 may be fastened to the part of the mounting member or plate 300 that is above the dielectric liquid coolant using any of the fastening methods disclosed above. In such a case, heat sinks 320 may thermally be attached to both sides of the HDDs 240. The heat sinks 320 may also be thermally coupled to the mounting plate 300. Since both the HDDs 240 and heat sinks 320 are thermally attached to the mounting plate 300, which is made of aluminum, the mounting plate 300 is used as a yet larger heat sink. The heat sinks 320 may also have a portion thereof immersed in the dielectric liquid coolant for enhanced cooling.

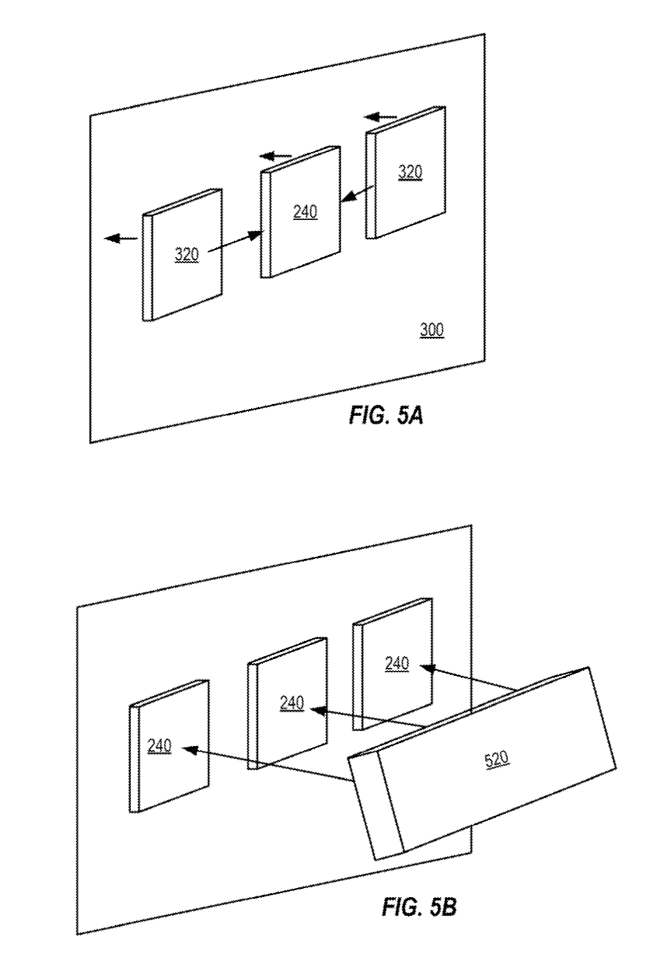

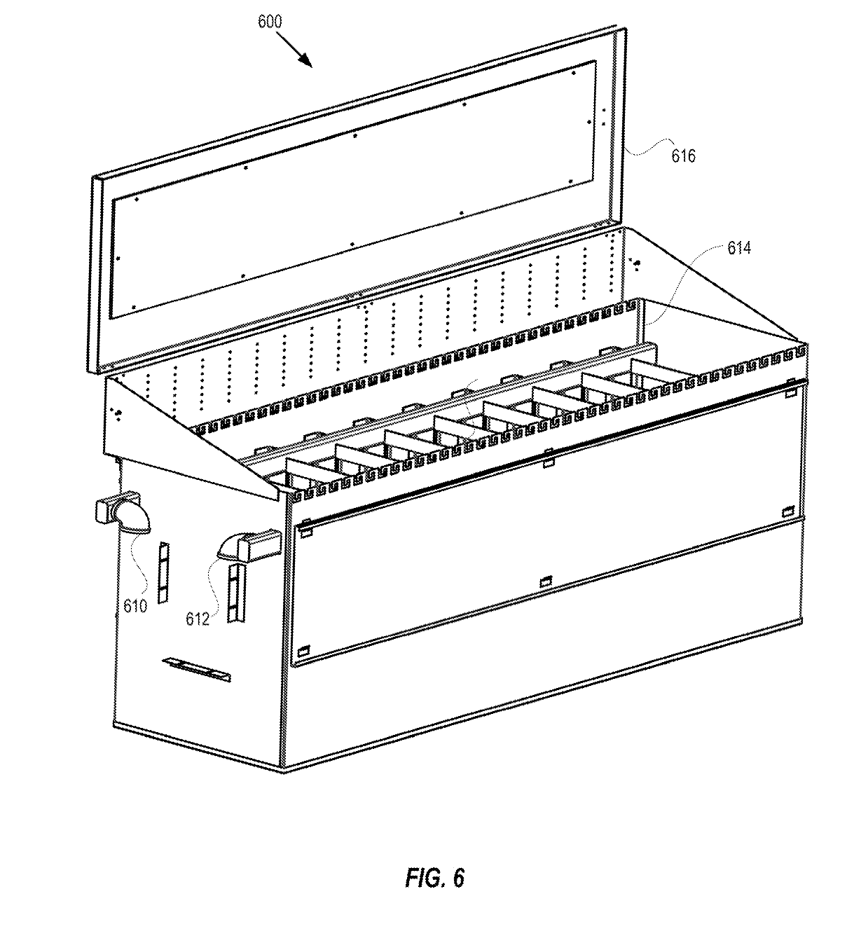

FIG. 5a displays two heat sinks 320 each thermally coupled to a side of an HDD 240. The heat sinks 320 are also shown to be thermally coupled to the mounting member or plate 300. In an alternative embodiment depicted in FIG. 5(b), a heat sink 520 is shown disposed over the HDDs 240 instead of being attached to the sides of the HDDs 240. In such a case, the heat sink 520 may also act as a shield or splash guard to protect the HDDs 240 from any splashing of the dielectric liquid coolant in the tank 200. Note that FIGS. 5a and 5b may be combined such that heat sinks 320 are attached to the sides of the HDDs 240 while heat sink 520 is on top of HDDs 240 for enhanced cooling purposes.

However, a preferential embodiment includes the use of drive caddies or their equivalent. Specifically, HDDs fail more often than other components of the computing systems 230. As a result, conventional rack-mountable computing systems 230 are designed to allow the HDDs to be replaced easily without removing any of the other components. To be removed and replaced easily, an HDD sits in a hard drive carrier, commonly called a drive caddy. The drive caddy is usually located in a slot (or HDD slot) in the front of the conventional computing systems. The drive caddy provides a handle that may be used to pull the drive out of the HDD slot. In addition, the drive caddy provides connector alignment. Connector alignment, ensures that when the HDD is inserted into the HDD slot in front of the computing system, mating electrical connectors of the HDD and the computing system align properly.

Since In the case of the present invention, the computing system is submerged in the dielectric liquid coolant, the HDD slot into which the drive caddy is inserted may face the surface 250 of the dielectric liquid coolant. To ensure that the HDD remain above the surface 250 of the dielectric liquid coolant while the HDD connector engages the mating computing system connector, the drive caddy is replaced with a drive sled. Unlike a drive caddy which is roughly the size of the hard drive therein, the drive sled is sufficiently longer than the HDD. This allows part of the drive sled to be below the surface 250 and part of it to be above the surface 250 of the dielectric liquid coolant when the HDD 240 is electrically connected to the computing system 230. The HDD 240 is fastened to the part of the drive sled that is above the surface 250 of the dielectric liquid coolant.

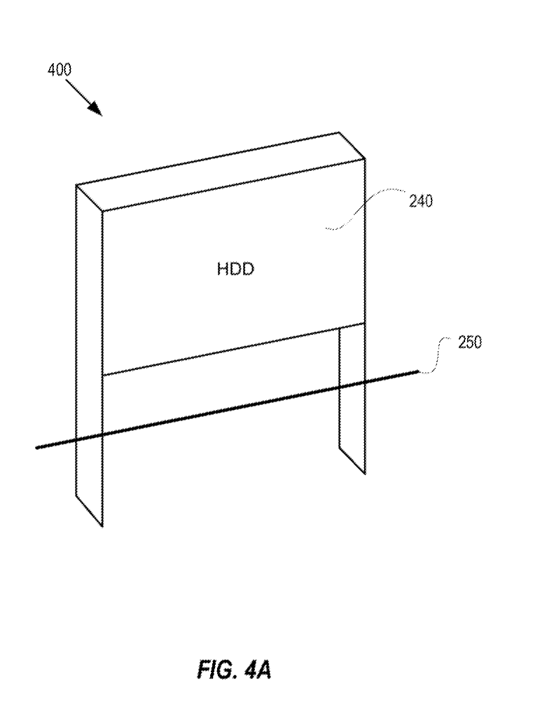

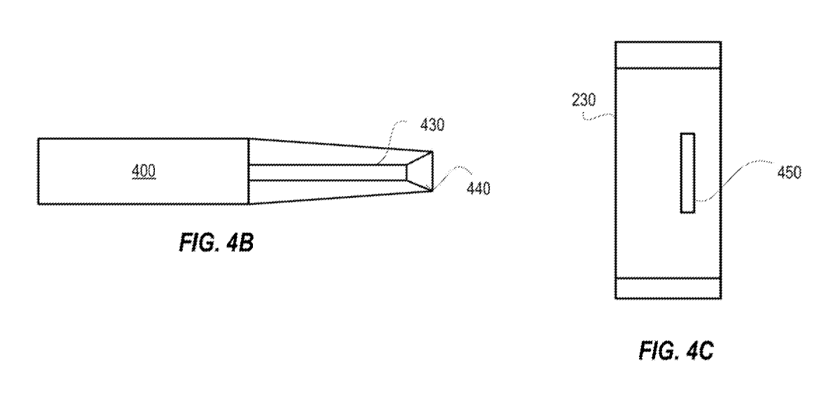

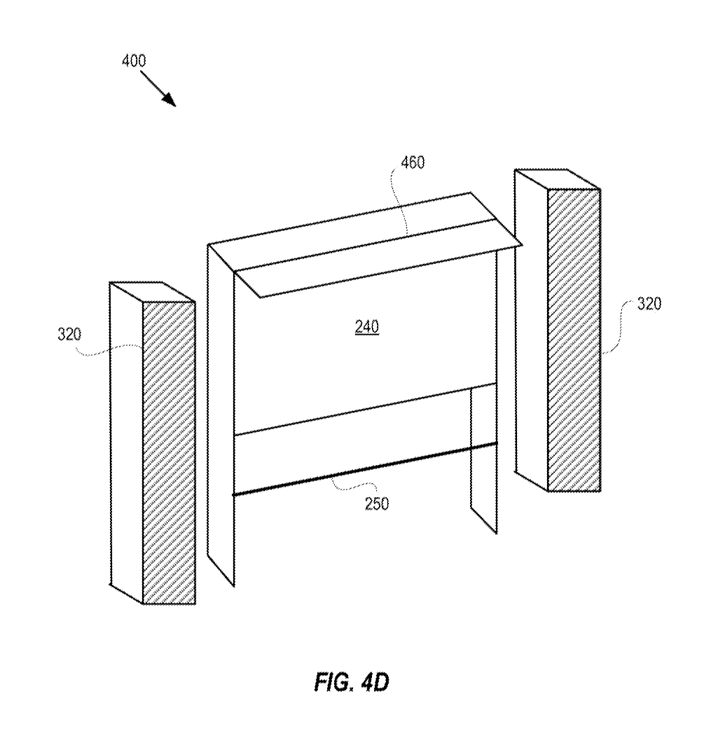

FIG. 4a depicts an exemplary drive sled 400 to which an HDD 240 is attached. The HDD 240 may be attached to the drive sled via any of the various fastening methods mentioned above (e.g., screws, slots, rails etc.). Preferably, a thin layer of soft, heat conducting material is placed between the HDD and the drive sled. A suitable material is a material commonly called thermal paste or a thermal pad.

To connect the HDD 240 to the computing system, a daughter board may be provided on the end of the sled that is submerged in the dielectric liquid coolant. A cable may then electrically connect the HDD to the daughter board. In such a case, the drive sled 400 may be designed to fit into the HDD slot of a conventional drive caddy. As the drive sled 400 is inserted into the HDD slot, the daughter board will mate with the mating connector on the computing system. Note that since part of the drive sled is submerged in the dielectric liquid coolant, the drive sled 400 is made of a heat conductive material, such as aluminum, to conduct heat away from the HDD 240 and into the dielectric liquid coolant.

FIG. 4b illustrates a drive sled 400 with an extension cable 430 and FIG. 4c depicts a computing system 230 with an HDD slot 450 facing up. At the end of the extension cable 430 within the dielectric liquid coolant is daughter board 440. The computing system connector is within HDD slot 450 of the computing system 230. The daughter board 440 is designed to fit into the slot 450 to electrically connect the HDD 240 to the computing system 230. Thus, this embodiment allows for “hot swapping” of HDDs 240 while the computing systems 230 remain submerged in the coolant. Hot swapping also allows the HDDs 240 to be replaced without shutting down the computing systems 230.

To provide for more cooling of the HDDs 240, the sled may have heat sinks 320 attached on either side of it. FIG. 4d illustrates a sled having heat sinks 320 attached on its sides. The sled has a handle 460 for facilitating removing the HDD 240 from the cooling system 200.

Returning to FIG. 2a, the dielectric liquid coolant heated by the computing systems 230 and HDDs 240 is fluidly coupled through suitable piping or lines to a pump 212. The pump 212 pumps the heated liquid coolant through suitable piping or lines to a heat exchanger 216, which is associated with a heat-rejection or cooling apparatus 218. Before getting to the heat exchanger 216, however, the dielectric liquid coolant may go through a filter 214 to filter out any foreign material that may have entered into the coolant.

The heat exchanger 216 rejects the heat from the incoming heated liquid coolant and fluidly couples the cooled liquid coolant through a return fluid line or piping 220 back into the tank 210. The heat rejected from the heated liquid coolant through the heat exchanger 216 may then be selectively used by alternative heat rejection or cooling apparatus 218 to dissipate, recover, or beneficially use the rejected heat depending on different environmental conditions and/or computing system operating conditions to which the system is subjected.

Note that either or both the heat exchanger 216 and the cooling apparatus 218 may be local or remote to the cooling system 200. However, since the cooling system 218 may generate heat when in operation, it may be beneficial that it be located remotely, or away from the cooling system 200.

The system 200 includes a controller 270 of conventional design with suitable novel applications software for implementing the methods of the present invention. The controller 270 may receive monitor signals of various operational parameters from various components of the cooling system 200 and the environment and may generate control signals to control various components of the cooling system 200 to maintain the heated liquid coolant exiting the servers in the tank at a specific elevated temperature in order to sufficiently cool each of the computing systems 230 and HDDs 240 while reducing the total amount of energy needed to cool the computing systems and HDDs. Particularly, the controller 270 monitors the temperature of the liquid coolant at at least one location within the fluid circuit, for example where the heated liquid circuit exits the plurality of computing systems and heat conductive extensions. The controller 270 may also monitor the temperature of the heat generating electronic components in the computing systems 230 as well as the heat generating electronic and mechanical components of the HDDs 240 by electrically connecting the controller 270 to the diagnostic output signals generated by conventional rack-mountable computing systems. The controller may also monitor the flow of the dielectric liquid coolant. Based upon such information, the controller 270 may output signals to the pump 212 and heat rejection or cooling apparatus 218 to adjust the flow of the liquid coolant through the fluid circuit and the amount of the heat being rejected by the heat rejection or cooling apparatus 218 for sufficiently cooling each respective computing system 230 and HDD 240 while maintaining the heated liquid coolant exiting the computing systems and heat conductive extensions of the HDDs 240 at the elevated temperature to reduce the amount of energy consumed to sufficiently cool each of the computing system 230 and HDD 240 in the system.

FIG. 2b is an alternative system to the exemplary system of FIG. 2a. As in FIG. 2a, FIG. 2b depicts a system 200 for cooling one or more rack-mountable computing systems 230 as well as one or more HDDs 240 simultaneously. Both the computing systems 230 and HDDs 240 may be arranged in one or more racks in a data center.

The system 200 includes a tank 210 having an interior volume containing a dielectric liquid coolant. The dielectric liquid coolant has a surface 250. Both the computing systems 230 and HDDs 240 may be mounted inside the tank 210 using the mounting members described above.

Unlike the cooling system 200 of FIG. 2a, the heated dielectric liquid coolant of FIG. 2b does not flow outside the tank 210. Instead, the fluid circuit of the flowing dielectric liquid coolant is completely internal to the tank 210. A thermal coupling device 216, such as a heat exchanger, is mounted within the tank 210 and the fluid circuit goes through the computing systems 230 and heat conductive extensions holding the HDDs 240 so that at least a portion of the heated dielectric liquid coolant flow exiting the computing systems and beat conductive expansions, flows through the thermal coupling device 216. Cooled dielectric liquid coolant exits the coupling device 216 and at least a portion of the cooled dielectric coolant circulates in the internal fluid circuit back through the computing systems 230 and the heat conductive extensions. The heat conductive extensions may be HDD sleds 400 or mounting plates 300 described above.

The system 200 includes a secondary heat rejection or cooling apparatus 218 having a cooling fluid, such as a gas or liquid flowing in piping or lines, forming a second fluid circuit wherein the secondary cooling apparatus 218 includes an associated heat exchanger (not shown) that may be local or remote to the system 200 to reject heat from the cooling fluid in the second fluid circuit through the second heat exchanger. The heat rejected from the heated cooling fluid in the second fluid circuit through the heat exchanger associated with the secondary cooling apparatus may then be selectively dissipated, recovered, or beneficially used depending on the different environmental conditions and/or computing system operating conditions to which the system is subject

The system 200 includes a controller 270 with suitable novel applications software for implementing the methods of the present invention. As the controller of FIG. 2a, the controller 270 of FIG. 2b may receive monitor signals of various operational parameters from various components of the cooling system 200 and the environment and may generate control signals to control various components of the cooling system to maintain the heated liquid coolant exiting the computing systems in the tank 210 at a specific temperature in order to sufficiently cool each of the plurality of computing systems 230 and HDDs 240 while reducing the total amount of energy needed to cool the computing systems.

Particularly, the controller 270 monitors the temperature of the liquid coolant at at least one location within the internal fluid circuit, for example, where the heated liquid circuit exits the computing systems immersed in the tank 210. The controller 270 may also monitor the temperature of the heat-generating electronic components in the computing systems 230 and HDDs 240 by electrically connecting the controller to the diagnostic output signals generated by conventional rack-mountable computing systems.

The controller 270 may also monitor the flow and temperature of the cooling fluid in the external fluid circuit. Based upon such information, the controller 270 may output signals to the heat rejection or cooling apparatus 218 to adjust the flow of the cooling liquid through the external fluid circuit and the amount of the heat being rejected by the heat rejection or cooling apparatus 218 for sufficiently cooling each respective computing system and HDD while maintaining the heated liquid coolant exiting the computing systems and heat conductive extensions at the specific temperature to reduce the amount of energy consumed to sufficiently cool each of the computing systems.

By maintaining the existing coolant at an elevated level, the cooling system may be used with a number of different techniques for using or dissipating the heat (e.g., heat recapture, low power heat dissipation, or refrigeration).

In some embodiments, an average bulk fluid temperature of the coolant can be maintained at a temperature of about, for example, 105° F. in temperate climates, which is significantly higher than a typical room temperature, as well as significantly higher the maximum average outdoor temperature by month in the U.S. (e.g., about 75° F. during summer months). At a temperature of about 105° F., heat can be rejected to the ambient environment of a temperate latitude during significant portions of a year (e.g., the atmosphere or nearby cooling sources such as rivers) with little power consumed, or recaptured as by, for example, heating the same or an adjacent building's hot-water supply or providing indoor heating in cold climates.

By maintaining a coolant temperature in excess of naturally occurring temperatures, irreversibilities and/or temperature differences present in a computing system cooling system may be reduced. A reduction in irreversibilities in a thermodynamic cycle tends to increase the cycle's efficiency, and may reduce the overall power consumed for cooling the computing systems.

In a conventional cooling system, about one-half watt is consumed by the cooling system for each watt of heat generated in a component. For example, a cooling medium (e.g., air) can be cooled to about 65° F. and the components to be cooled can operate at a temperature of about, for example, 158° F. This large difference in temperature results in correspondingly large inefficiencies and power consumption. In addition, the “quality” of the rejected heat is low, making the heat absorbed by the cooling medium difficult to recapture after being dissipated by the components). However, with a cooling medium such as air, such a large temperature difference may be necessary in conventional systems in order to achieve desired rates of heat transfer.

FIG. 6 depicts an exemplary tank 600 with an interior volume within which computing systems 230, HDDs 240 and dielectric liquid coolant are kept. The tank 600 may have a lid 616 that can be opened to insert or remove computing systems 230 and HDDs 240 but it need not be sealed during operation. The interior volume of the tank 600 includes a rack system 614 for holding the computing systems 230 and HDDs 240. The tank 600 also has on one side a coolant inlet 612 and a coolant outlet 610. Note that although the coolant inlet 612 and the coolant outlet 610 are on one side of the tank 600, the invention is not thus restricted. The coolant inlet 612 and the coolant outlet 610 may be located on any of the sides of the tank 600 as well as may each be located on a different side of the tank 600. Thus, showing the coolant inlet 612 and the coolant outlet 610 on that particular side of the tank 600 is for illustrative purposes only.

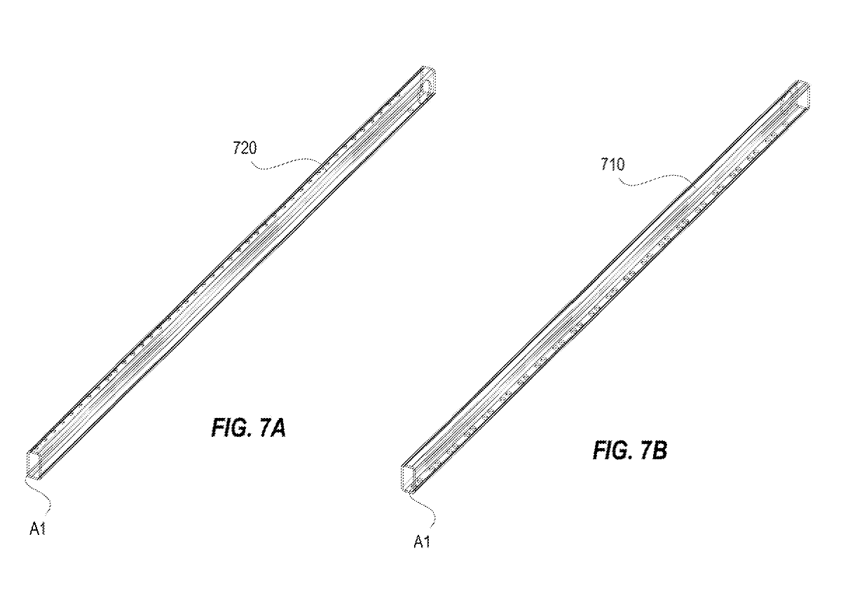

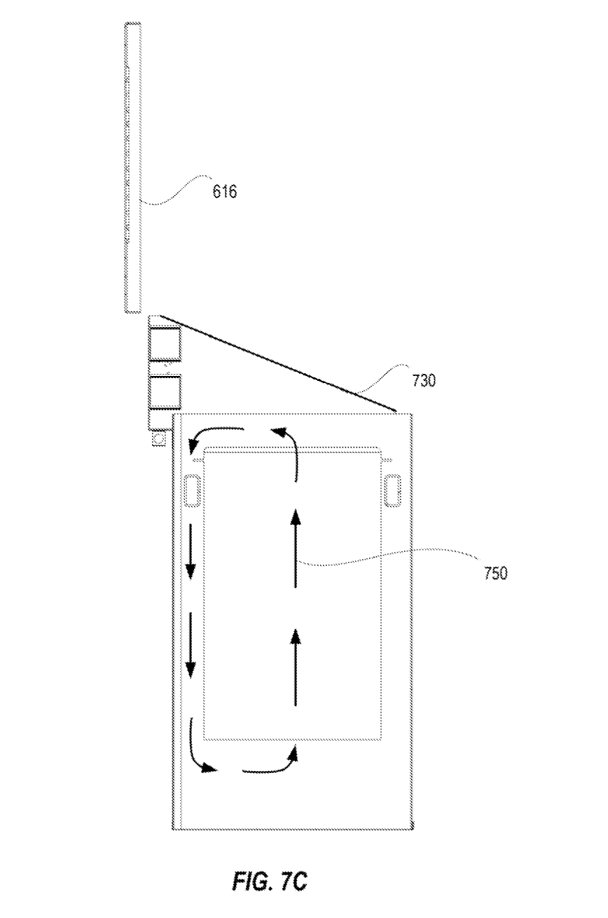

FIGS. 7a and 7b depict a suction manifold 720 and a pressure manifold 710. respectively. The pressure manifold 710 is attached to the coolant inlet 612 and the suction manifold 720 is attached to the coolant outlet 610 inside the interior volume of the tank 600. Both the suction manifold 720 and pressure manifold 710 have an area A₁. Further, both the suction manifold 720 and the pressure manifold 710 have a plurality of nozzles or velocity augmentation devices of area A₂ distributed along their length.

The area A₂ of the velocity augmentation devices along the length of the pressure manifold 710 is much smaller than the area A₁ of the pressure manifold 710. This allows for the pressure lost through the velocity augmentation devices to be much greater than the pressure lost through the pressure manifold 710. Consequently, the pressure across the velocity augmentation devices is approximately equal over the entire length of the tank 600. Likewise, suction across the suction manifold 720 is approximately equal along the entire length of the tank 600. Hence, coolant flow is approximately equal along the length of the entire tank 600.

In any case, as the dielectric liquid coolant comes out of the velocity augmentation devices along the length of the pressure manifold 710, the movement or flow of the coolant accelerates. This results in an increase in flow of the bulk of the coolant inside the tank 600, as well as an improvement in the direction of the flow of the coolant. The resulting bulk coolant movement forces a circular flow of coolant in the tank 600. The flow cycle goes around the outside of the computing systems 230 and the drive sleds of the HDDs 240, accelerates around the velocity augmentation devices, flowing downward and then flows upward through the computing systems 230 and drive sleds of the HDDs 240, out the top of the computing systems 230 and then back around the velocity augmentation devices.

FIG. 7c is a left side view of the tank 600. In the figure, the lid 616 is removed and a baffle 730 that is integrated in the suction manifold 720 is shown. Baffle 730 may be used to prevent the dielectric liquid coolant from going around the computing system in the earlier mentioned coolant flow. In any case, circular arrow 750 shows one possible flow direction of the dielectric liquid coolant in the tank 600.

Note that different suction manifolds 720 may be used to adjust for higher or lower localized heat. For example, if a particular area of a tank 600 is too hot, a suction manifold 720 having more nozzles in that particular area may be used to intensify the flow of the coolant around that area.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

What is claimed is:

1. A system for cooling one or more hard disk drives of one or more computing systems, the one or more hard disk drives having heat generating electronic and mechanical components, the system comprising:
a dielectric liquid coolant;
at least one tank defining an interior volume for holding the dielectric coolant;
first one or more members positioned within the interior volume for mounting the one or more computing systems thereon, the first one or more mounting members being configured to allow the one or more computing systems to be at least partially submerged within the dielectric liquid coolant when the dielectric liquid coolant is in the interior volume for sufficiently cooling the one or more computing systems;
second one or more mounting members positioned within the interior volume for mounting the one or more hard disk drives thereon, the second one or more mounting members being configured to keep the one or more hard disk drives mounted thereon above the dielectric liquid coolant when the dielectric liquid coolant is in the interior volume, the second one or more mounting members having at least one heat conductive extension thermally coupled with the one or more hard disk drives at one end and immersed into the dielectric liquid coolant at another end, the at least one heat conductive extension for transferring at least a portion of heat generated by the heat generating electronic and mechanical components of the one or more hard disk drives to the dielectric liquid coolant for absorption in order to sufficiently cool the one or more hard disk drives;
a heat exchanger thermally coupled to the dielectric liquid coolant for cooling the dielectric liquid coolant in the tank.

2. The system of claim 1 further including a splash guard coupled to the one or more hard disk drives for protecting the one or more hard disk drives against dielectric liquid coolant splashes from circulating dielectric liquid coolant in the tank.

3. The system of claim 1 further including at least one heat sink thermally coupled to the at least one heat conductive extension, the at least one heat sink being immersed at one end into the dielectric liquid coolant for coupling heat from the hard disk drives to the dielectric liquid coolant, thereby providing further cooling to the hard disk drive.

4. The system of claim 1 wherein the at least one heat conductive extension includes an electrical connector at the end immersed in the dielectric liquid coolant, the one or more computing systems having at least one hard disk drive slot having a mating electrical connector therein, the electrical connector being connected to the one or more hard disk drives at one end and to the mating connector at another end to thereby electrically connect the one or more hard disk drives to the one or more computing systems.

5. The system of claim 1 further including a controller, the controller for maintaining the dielectric liquid coolant at substantially a particular temperature.

6. The system of claim 1 further including a controller for maintaining the dielectric liquid coolant at a specific elevated temperature, the specific elevated temperature being a temperature that sufficiently cools the one or more computing systems and the one or more hard disk drives while reducing energy consumption.

7. The system of claim 6 further including a pump for pumping warmer dielectric liquid coolant from the interior volume of the tank and for pumping cooler dielectric liquid coolant into the interior volume of the tank.

8. The system of claim 7 wherein the at least one tank includes a coolant inlet and a coolant outlet, a pressure manifold on one side and a suction manifold on another side, the pressure manifold being fluidly coupled to a coolant inlet for facilitating the flow of the cooler dielectric liquid coolant into the interior volume and the suction manifold being fluidly coupled to the coolant outlet for facilitating the flow of the warmer dielectric liquid coolant out of the interior volume.

9. The system of claim 8 wherein the pressure manifold and the suction manifold having a plurality of flow augmentation devices for enhancing and directing the flow of the dielectric liquid coolant inside the interior volume.

10. An apparatus for cooling one or more hard disk drives of one or more computing systems, the one or more hard disk drives having heat generating electronic and mechanical components, the apparatus comprising:
at least one tank defining an interior volume for holding a dielectric liquid coolant;
first one or more members positioned within the interior volume for mounting the one or more computing systems thereon, the first one or more mounting members being configured to allow the one or more computing systems to be at least partially submerged within the dielectric liquid coolant when the dielectric liquid coolant is in the interior volume for sufficiently cooling the one or more computing systems;
second one or more mounting members positioned within the interior volume for mounting the one or more hard disk drives thereon, the second one or more mounting members being configured to keep the one or more hard disk drives mounted thereon above the dielectric liquid coolant when the dielectric liquid coolant is in the Interior volume, the second one or more mounting members having at least one heat conductive extension thermally coupled with the one or more hard disk drives at one end and immersed into the dielectric liquid coolant at another end, the at least one heat conductive extension for transferring at least a portion of heat generated by the heat generating electronic and mechanical components of the one or more hard disk drives to the dielectric liquid coolant for absorption in order to sufficiently cool the one or more hard disk drives;
a heat exchanger thermally coupled to the dielectric liquid cooling for cooling the dielectric liquid coolant in the tank.

11. The apparatus of claim 10 further including a splash guard coupled to the one or more hard disk drives for protecting the one or more hard disk drives against dielectric liquid coolant splashes from circulating dielectric liquid coolant in the tank.

12. The apparatus of claim 10 further including at least one heat sink thermally coupled to the at least one heat conductive extension, the at least one heat sink being immersed at one end into the dielectric liquid coolant for coupling heat from the hard disk, drives to the dielectric liquid coolant, thereby providing further cooling to the hard disk drive.

13. The apparatus of claim 10 wherein the at least one heat conductive extension includes an electrical connector at the end immersed in the dielectric liquid coolant, the one or more computing systems having at least one hard disk drive slot having a mating electrical connector therein, the electrical connector being connected to the one or more hard disk drives at one end and to the mating connector at another end to thereby electrically connect the one or more hard disk drives to the one or more computing systems.

14. The apparatus of claim 10 further including a controller, the controller for maintaining the dielectric liquid coolant at substantially a particular temperature.

15. The apparatus of claim 10 further including a controller, the controller for maintaining the dielectric liquid coolant at a specific elevated temperature, the specific elevated temperature being a temperature that sufficiently cools the one or more computing systems and the one or more hard disk drives while reducing energy consumption.

16. The apparatus of claim 15 further including a pump for pumping warmer dielectric liquid coolant from the interior volume and for pumping cooler dielectric liquid coolant into the interior volume.

17. The apparatus of claim 16 wherein the at least one tank includes a coolant inlet and a coolant outlet, a pressure manifold on one side and a suction manifold on another side, the pressure manifold being fluidly coupled to a coolant inlet for facilitating the flow of the cooler dielectric liquid coolant into the interior volume and the suction manifold being fluidly coupled to the coolant outlet for facilitating the flow of the warmer dielectric liquid coolant out of the interior volume.

18. The apparatus of claim 17 wherein the pressure manifold and the suction manifold having a plurality of flow augmentation devices for enhancing and directing the flow of the dielectric liquid coolant inside the interior volume.

19. A method of cooling one or more hard disk drives of one or more computing systems, the one or more hard disk drives having heat generating electronic and mechanical components, the method comprising;
a dielectric liquid coolant;
holding a dielectric liquid coolant in at least one tank defining an interior volume;
mounting the one or more computing systems to a first one or more members positioned within the interior volume, the first one or more mounting members being configured to allow the one or more computing systems to be at least partially submerged within the dielectric liquid coolant when the dielectric liquid coolant is in the interior volume for sufficiently cooling the one or more computing systems;
mounting the one or more hard disk drives to a second one or more mounting members positioned within the interior volume, the second one or more mounting members being configured to keep the one or more hard disk drives mounted thereon above the dielectric liquid coolant when the dielectric liquid coolant is in the interior volume, the second one or more mounting members having at least one heat conductive extension thermally coupled with the one or more hard disk drives at one end and immersed into the dielectric liquid coolant at another end, the at least one heat conductive extension for transferring at least a portion of heat generated by the heat generating electronic and mechanical components of the one or more hard disk drives to the dielectric liquid coolant for absorption in order to sufficiently cool the one or more hard disk drives;
cooling the dielectric liquid coolant in the tank with a heat exchanger.

20. The method of claim 19 further including protecting the one or more hard disk drives with a splash guard coupled thereto against dielectric liquid coolant splashes from circulating dielectric liquid coolant in the tank.

21. The method of claim 19 further including thermally coupling at least one heat sink to the at least one heat conductive extension, the at least one heat sink being immersed at one end into the dielectric liquid coolant for coupling heat from the hard disk drives to the dielectric liquid coolant, thereby providing further cooling to the hard disk drive.

22. The method of claim 19 wherein the at least one heat conductive extension includes an electrical connector at the end immersed in the dielectric liquid coolant, the one or more computing systems having at least one hard disk drive slot having a mating electrical connector therein, the electrical connector being connected to the one or more hard disk drives at one end and to the mating connector at another end to thereby electrically connect the one or more hard disk drives to the one or more computing systems.

23. The method of claim 19 further including using a controller for maintaining the dielectric liquid coolant at substantially a particular temperature.

24. The method of claim 19 further including a controller, the controller for maintaining the dielectric liquid coolant at substantially a specific elevated temperature, the specific elevated temperature being a temperature that sufficiently cools the one or more computing systems and the one or more hard disk drives while reducing energy consumption.

25. The method of claim 24 further including pumping warmer dielectric liquid coolant from the interior volume and for pumping cooler dielectric liquid coolant into the interior volume using a pump.

26. The method of claim 25 wherein the at least one tank includes a coolant inlet and a coolant outlet, a pressure manifold on one side and a suction manifold on another side, the pressure manifold being fluidly coupled to a coolant inlet for facilitating the flow of the cooler dielectric liquid coolant into the interior volume and the suction manifold being fluidly coupled to the coolant outlet for facilitating the flow of the warmer dielectric liquid coolant out of the interior volume wherein the pressure manifold and the suction manifold having a plurality of flow augmentation devices for enhancing and directing the flow of the dielectric liquid coolant inside the interior volume.
